(19) United States
(12) Patent Application Publication
(10) Pub. No.: US 2011/0284931 A1
(43) Pub. Date: Nov. 24, 2011

(54) transistor device and manufacture method

(75) Inventors: Wen-Chau Liu, Tainan City (TW); Huey-Ing Chen, Tainan City (TW); Li-Yang Chen, Tainan City (TW); Chien-Chang Huang, Tainan City (TW)

(73) Assignee: NATIONAL CHENG KUNG UNIVERSITY, Tainan City (TW)

(21) Appl. No.: 13/112,804

(22) Filed: May 20, 2011

(30) Foreign Application Priority Data
May 21, 2010 (TW) 099116245

(51) Int. Cl. H01L 29/772; H01L 21/338

(52) U.S. Cl. 257/280; 438/167; 257/E29.242; 257/E21.45

(57) ABSTRACT

A transistor device sequentially comprises a semiconductor substrate, a drain, a source, a gate metal seed layer and a gate Schottky contact. The gate metal seed layer comprises a gelatinous substance layer and multiple metal seed crystals. A manufacture method comprises steps of providing a semiconductor substrate; forming a drain and a source; forming a patterned photoresist layer with a photolithography to define a gate area on the semiconductor substrate; forming a gate metal seed layer on the semiconductor substrate with a sensitization process and an activation process; and forming a gate Schottky contact on the gate metal seed layer with an electroless plating approach.

### CROSS-REFERENCE TO RELATED APPLICATIONS

This non-provisional application claims priority under 35 U.S.C. §119(a) on Patent Application No. 099116245, filed in Taiwan, R.O.C. on May 21, 2010, the entire contents of which are hereby incorporated by reference.

### FIELD OF THE INVENTION

The present invention is a transistor device and a manufacture method.

### BACKGROUND OF THE INVENTION

Gallium nitride (GaN) is a binary III/V direct bandgap semiconductor. It exhibits wide band gap, high breakdown voltage, good bonding force, and good thermal stability for applications in field effect transistors (FET).

U.S. Pat. No. 5,866,925 discloses an all-ion implanted gallium-nitride (GaN) junction field-effect transistor (JFET) and method of making the JFET. Also disclosed are various ion implants, both n- and p-type, together with or without phosphorous co-implantation, in selected III-V semiconductor materials.

However, the previous gallium nitride based (GaN-based) transistors, which used a conventional physical vacuum deposition processes to form a gate metal, exhibits an obviously Fermi-level pinning effect, poor Schottky interface, much more surface defects, and energy consumption.

Accordingly, a new manufacture method for the GaN-based transistor is needed to prevent the previous problems.

### SUMMARY OF THE INVENTION

The primary objective of the present invention is to prevent poor Schottky interface, reduce surface defects, decrease energy consumption, shorten an induction period during electroless plating reaction, reduce a metal grain size, and comprises a transistor device and a manufacture method.

The transistor device comprises a semiconductor substrate, a drain, a source, a gate metal seed layer which forms by sensitization and activation processes, and a gate Schottky contact metal which forms by an electroless plating approach.

The drain forms on the semiconductor substrate. The source forms on the semiconductor substrate and does not overlap the drain. The gate metal seed layer forms on the semiconductor substrate, does not overlap the drain and the source and comprises a gelatinous substance layer and multiple metal seed crystals. The gate Schottky contact forms on the gate metal seed layer.

The manufacture method in accordance with the present invention comprises steps of providing a semiconductor substrate, forming a drain and a source on the semiconductor substrate, forming a patterning photoresist layer with a photoetching technique to define a gate zone of a gate metal seed layer on the semiconductor substrate, forming the gate metal seed layer on the semiconductor substrate with a sensitization process and an activation process, and forming a gate Schottky contact on the gate metal seed layer with an electroless plating approach.

### BRIEF DESCRIPTION OF THE DRAWINGS

FIG. 1 is a side view of the studied device in the present invention;

FIG. 2 is a sensitization process, an activation process and an electroless plating approach in the present invention;

FIG. 3 is a graph of gate leakage current versus gate drain voltage at different temperatures of the studied device in the present invention;

FIG. 4 is a typical common-source output I-V characteristics at different temperatures of the studied device in the present invention;

FIG. 5 is a transconductance and drain current versus gate source voltage at different temperatures of the studied device in the present invention;

FIG. 6 is a threshold voltage and variations of threshold voltage as a function of temperature of the studied device in the present invention;

FIG. 7 is a graph of drain current versus drain source voltage at different gate source voltages of the studied device in the present invention;

FIG. 8 is a responses measured diagram of the studied device in the present invention, wherein the temperature is 570 degree Kelvin, the gate source voltage is fixed at −2 volts and hydrogen concentration is 1 percent;

FIG. 9 is a response at different hydrogen concentrations of the studied device in the present invention, with a temperature of 570 degrees Kelvin and gate source voltage of −2 volts;

FIG. 10 is a flowchart of a fabricating method in the present invention; and

FIG. 11 is a flowchart of a step of providing a semiconductor substrate in the present invention.

### DETAILED DESCRIPTION OF THE PRESENT INVENTION

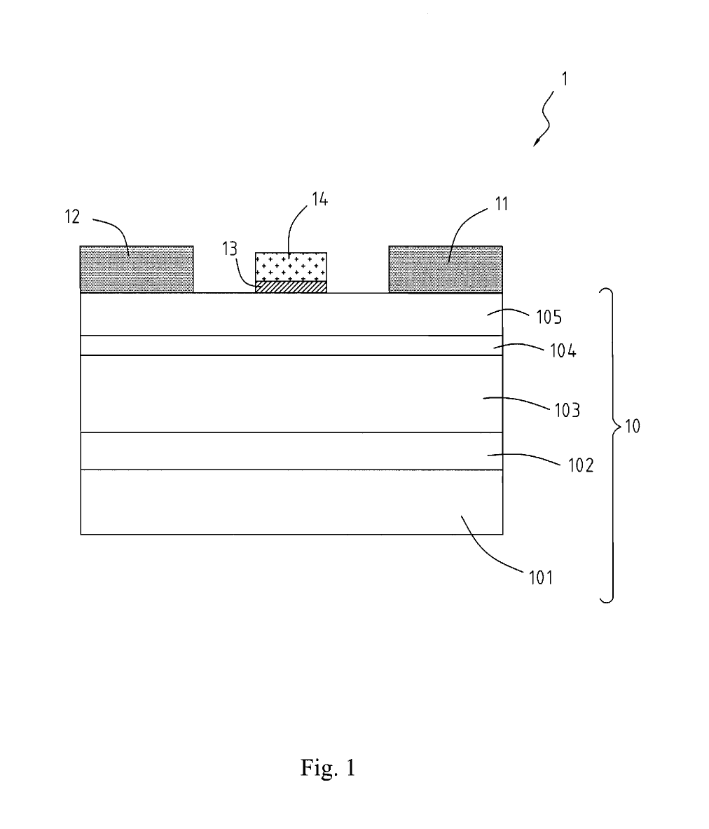

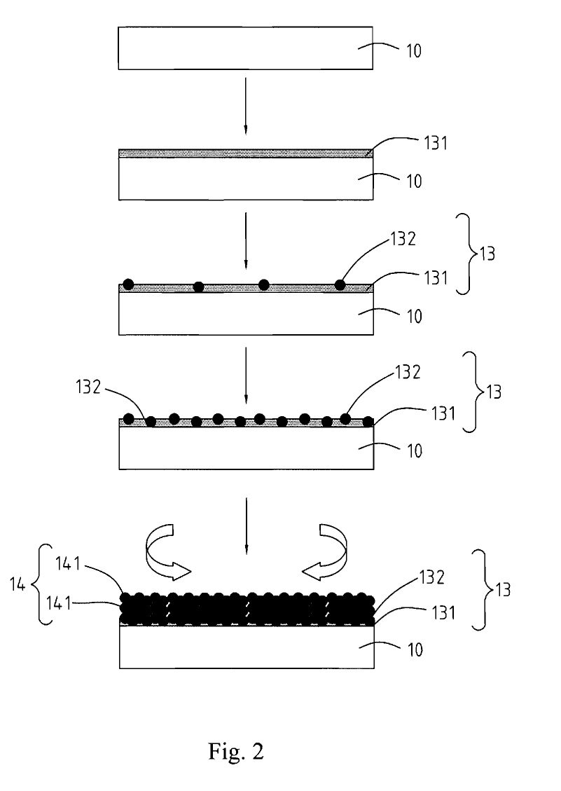

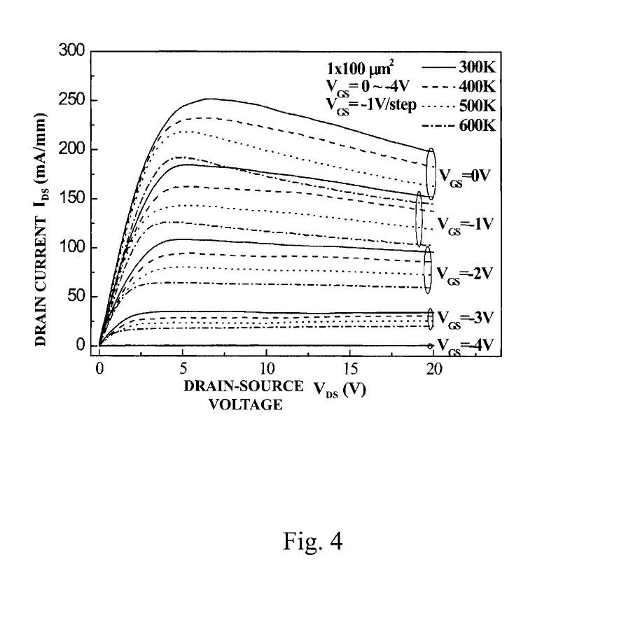

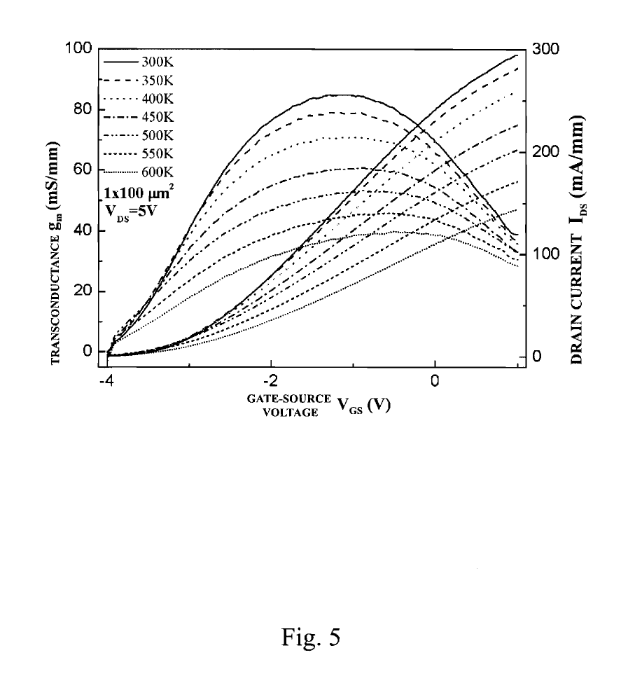

With reference to FIGS. 1, 2, 4 and 5, a transistor device (1) in accordance with the present invention enhances a Schottky characteristic, thermal stability of a metal-semiconductor interface, reliability of a Schottky barrier to metal work function and a carrier-confinement ability, reduces a Fermi-level pinning effect, reduces waste of energy, may be applied to a hydrogen sensor and comprises a semiconductor substrate (10), a drain (11), a source (12), a gate metal seed layer (13) and a Gate Schottky contact (14).

The transistor device (1) and has a gate drain voltage, a gate source voltage, a drain source voltage, a drain current, a gate leakage current, a breakover voltage, a threshold voltage, a threshold voltage shift and a transconductance.

The Schottky characteristic comprises an amplification characteristic, a saturation characteristic, a pinch-off characteristic, a high temperature characteristic and a high operational bias characteristic.

The semiconductor substrate (10) may comprise a substrate (101), a nucleation layer (102), a buffer layer (103), a channel layer (104) and metal contact layer (105).

The substrate (101) may be a semi-insulating material and may be a sapphire, silicon or carborundum material.

The nucleation layer (102) may form on the substrate (101), may be an undoped aluminum nitride material and may have a thickness in a range of 1 nanometer to 10,000 nanometers.

The buffer layer (103) may form on the nucleation layer (102), may be an undoped gallium nitride material and may have a thickness in a range of 0.01 micrometer to 50 micrometers.

The channel layer (104) may form on the buffer layer (103), may be an undoped aluminum gallium nitride (AlₓGa₁₋ₓN) and may have a thickness in a range of 1 angstrom (Å) to 3,000 angstroms (Å). The undoped aluminum gallium nitride may have an aluminum mole fraction that is in a range of 0.01 to 0.35.

The metal contact layer (105) may form on the channel layer (104), may be a doped aluminum gallium nitride (AlₓGa₁₋ₓN) and may have a thickness in a range of 1 angstrom (Å) to 30,000 angstroms (Å). The doped aluminum gallium nitride may have a doped concentration (n) and an aluminum mole fraction. The doped concentration is in a range of 1×10¹⁶ cm⁻³ to 5×10¹⁹ cm⁻³. The aluminum mole fraction is in a range of 0.01 to 0.35.

The drain (11) forms on the semiconductor substrate (10) and may be a titanium-aluminum-titanium-gold (Ti/Al/Ti/Au) alloy, a titanium-aluminum-nickel-gold (Ti/Al/Ni/Au) alloy, a titanium-aluminum-molybdenum-gold (Ti/Al/Mo/Au) alloy or a titanium-aluminum (Ti/Al) alloy.

The titanium-aluminum-titanium-gold (Ti/Al/Ti/Au) alloy has a first titanium thickness, an aluminum thickness, second titanium thickness and a gold thickness. The first titanium thickness is in a range of 1 nanometer to 1,000 nanometers. The aluminum thickness is in a range of 1 nanometer to 10,000 nanometers. The second titanium thickness is in a range of 1 nanometer to 1,000 nanometers. The gold thickness is in a range of 1 nanometer to 50,000 nanometers.

The titanium-aluminum-nickel-gold (Ti/Al/Ni/Au) alloy has a titanium thickness, an aluminum thickness, a nickel thickness and a gold thickness. The titanium thickness is in a range of 1 nanometer to 1,000 nanometers. The aluminum thickness is in a range of 1 nanometer to 10,000 nanometers. The nickel thickness is in a range of 1 nanometer to 1,000 nanometers. The gold thickness is in a range of 1 nanometer to 50,000 nanometers.

The titanium-aluminum-molybdenum-gold (Ti/Al/Mo/Au) alloy has a titanium thickness, an aluminum thickness, a molybdenum thickness and a gold thickness. The titanium thickness is in a range of 1 nanometer to 1,000 nanometers. The aluminum thickness is in a range of 1 nanometer to 10,000 nanometers. The molybdenum thickness is in a range of 1 nanometer to 1,000 nanometers. The gold thickness is in a range of 1 nanometer to 50,000 nanometers.

The titanium-aluminum (Ti/Al) alloy has a titanium thickness and an aluminum thickness. The titanium thickness is in a range of 1 nanometer to 1000 nanometers. The aluminum thickness is in a range of 1 nanometer to 50,000 nanometers.

The source (12) forms on the semiconductor substrate (10), does not overlap the drain (11) and may be a titanium-aluminum-titanium-gold (Ti/Al/Ti/Au) alloy, a titanium-aluminum-nickel-gold (Ti/Al/Ni/Au) alloy, a titanium-aluminum-molybdenum-gold (Ti/Al/Mo/Au) alloy or a titanium-aluminum (Ti/Al) alloy.

The titanium-aluminum-titanium-gold (Ti/Al/Ti/Au) alloy has a first titanium thickness, an aluminum thickness, second titanium thickness and a gold thickness. The first titanium thickness is in a range of 1 nanometer to 1,000 nanometers. The aluminum thickness is in a range of 1 nanometer to 10,000 nanometers. The second titanium thickness is in a range of 1 nanometer to 1,000 nanometers. The gold thickness is in a range of 1 nanometer to 50,000 nanometers.

The titanium-aluminum-nickel-gold (Ti/Al/Ni/Au) alloy has a titanium thickness, an aluminum thickness, a nickel thickness and a gold thickness. The titanium thickness is in a range of 1 nanometer to 1000 nanometers. The aluminum thickness is in a range of 1 nanometer to 10,000 nanometers. The nickel thickness is in a range of 1 nanometer to 1000 nanometers. The gold thickness is in a range of 1 nanometer to 50,000 nanometers.

The titanium-aluminum-molybdenum-gold (Ti/Al/Mo/Au) alloy has a titanium thickness, an aluminum thickness, a molybdenum thickness and a gold thickness. The titanium thickness is in a range of 1 nanometer to 1000 nanometers. The aluminum thickness is in a range of 1 nanometer to 10,000 nanometers. The molybdenum thickness is in a range of 1 nanometer to 1000 nanometers. The gold thickness is in a range of 1 nanometer to 50,000 nanometers.

The titanium-aluminum (Ti/Al) alloy has a titanium thickness and an aluminum thickness. The titanium thickness is in a range of 1 nanometer to 1,000 nanometers. The aluminum thickness is in a range of 1 nanometer to 50,000 nanometers.

The gate metal seed layer (13) is formed on the semiconductor substrate (10), does not overlap the drain (11) and the source (12), comprises a gelatinous substance layer (131) and multiple metal seed crystals (132) and may have a thickness that is in a range of 1 angstrom (Å) to 5000 angstroms (Å).

The gelatinous substance layer (131) may form on the semiconductor substrate (10), and may have a thickness in a range of 5 angstroms (Å) to 20 angstroms (Å) and has secondary metal seed crystals (132). The secondary metal seed crystals (132) may form on the gelatinous substance layer (131) and may be selected from a group consisting of a palladium (Pd) seed crystals, a silver (Ag) seed crystals and a gold (Au) seed crystals.

The Gate Schottky contact (14) is formed on the gate metal seed layer (13), may be multiple gate unit particles (141) and may have a thickness in a range of 2 angstroms (Å) to 50,000 angstroms (Å). The gate unit particles (141) are selected from a group consisting of palladium (Pd) particles, platinum (Pt) particles, nickel (Ni) particles and palladium-silver (Pd—Ag) particles.

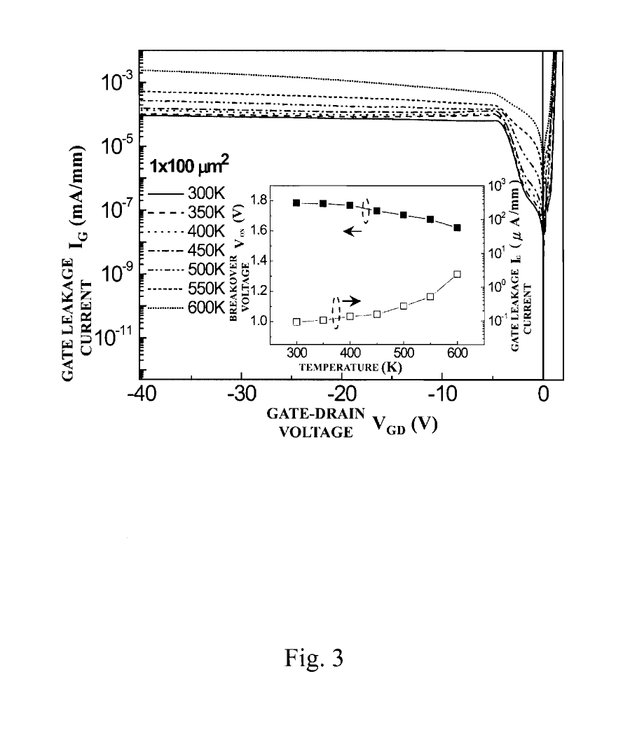

With further reference to FIG. 3, a gate-drain voltage (V_{GD}) of −40 volts, results in a gate leakage current of 0.09 μA/mm at 300 degrees Kelvin and 2.41 μA/mm at 600 degrees Kelvin. The gate leakage current is low and the breakover voltage is high at high temperature.

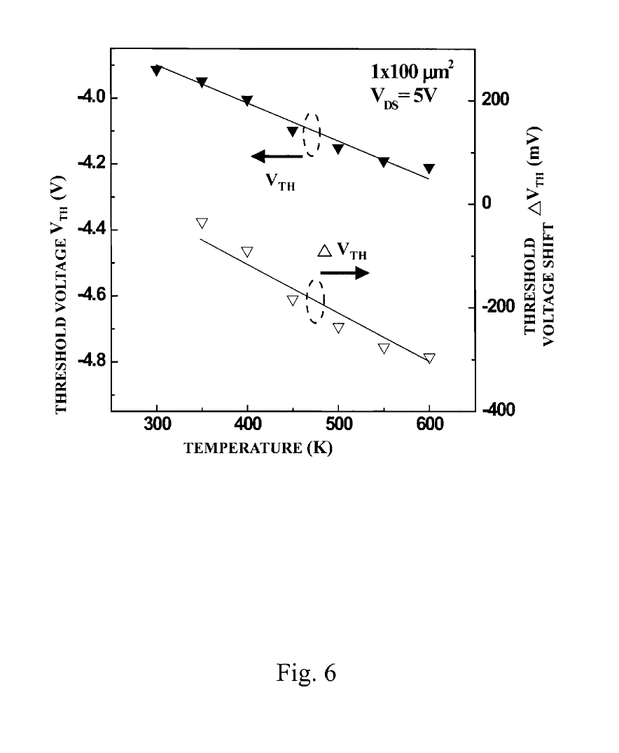

With further reference to FIG. 6, threshold voltage is −3.91 volts at 300 degrees Kelvin and −4.204 volts at 600 degrees Kelvin. When temperature is increased from 300 to 600 degrees Kelvin, threshold voltage only varies 294 millivolts.

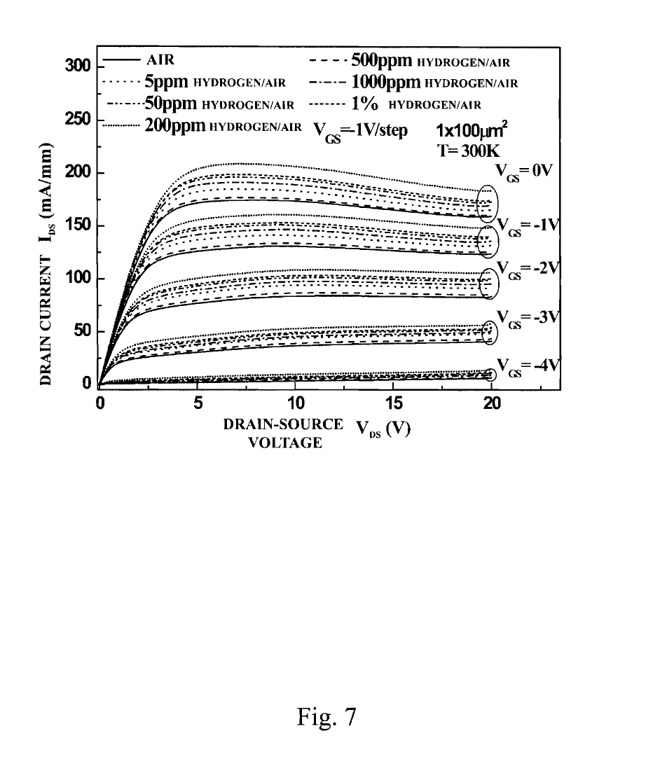

With further reference to FIG. 7, the hydrogen sensor senses hydrogen at 300 degrees Kelvin, and hydrogen concentration is 5 ppm H₂/Air.

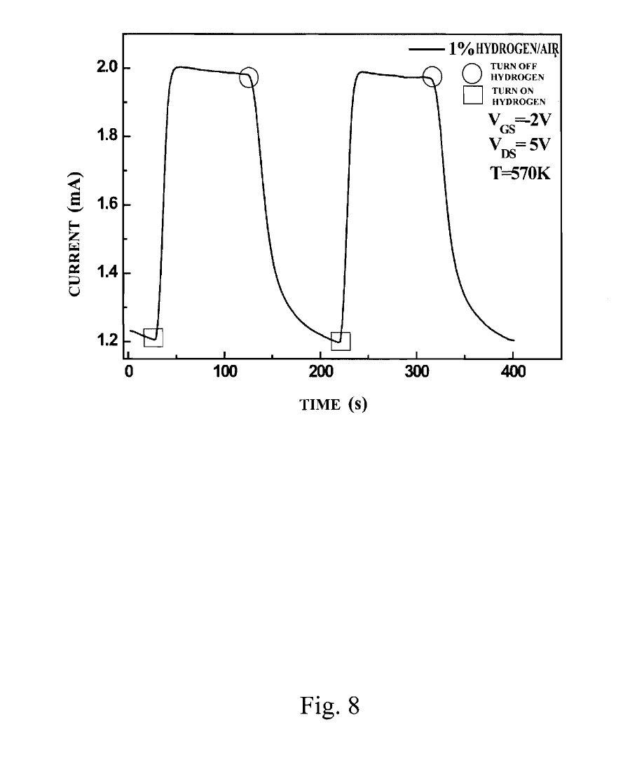

With further reference to FIG. 8, operational temperature is 570 degrees Kelvin, gas flow velocity is 400 cm³/min and drain source voltage is 5 volts. When hydrogen is turn on, a hydrogen atom forms an electric dipole moment layer, then Schottky barrier of the Gate Schottky contact (14) is decreased and current is increased quickly. When hydrogen is turn off, current is 1.2 milliamperes as current value in the air.

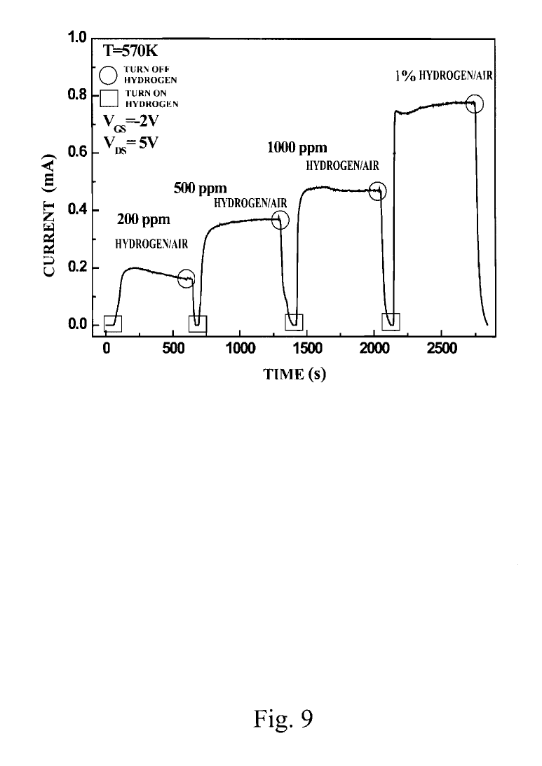

With further reference to FIG. 9, gas flow velocity is 400 cm³/min, drain source voltage is 5 volts and gate source voltage is −2 volts. The hydrogen sensor has good sensibility at 570 degrees Kelvin.

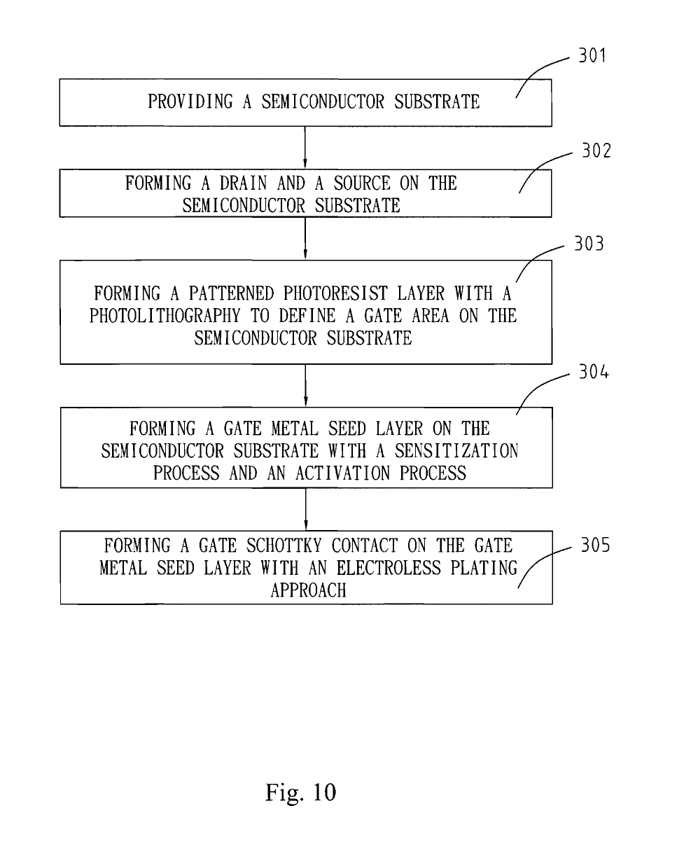

With further reference to FIG. 10, the manufacture method (3) in accordance with the present invention comprises steps of step (301) providing a semiconductor substrate, step (302) forming a drain and a source on the semiconductor substrate, step (303) forming a patterned photoresist layer with a photolithography to define a gate area on the semiconductor substrate, step (304) forming a gate metal seed layer on the semiconductor substrate with a sensitization process and an activation process, and step (305) forming a Gate Schottky contact on the gate metal seed layer with an electroless plating approach.

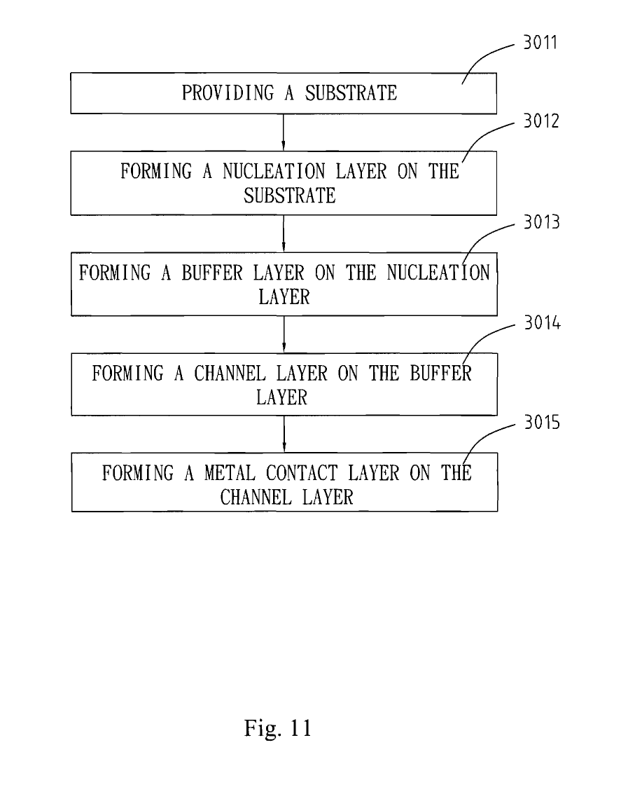

With further reference to FIG. 11, step (301) of providing a semiconductor substrate may comprise steps of step (3011) providing a substrate (101), step (3012) forming a nucleation layer (102) on the substrate, step (3013) forming a buffer layer (103) on the nucleation layer (102), step (3014) forming a channel layer (104) on the buffer layer (103), and step (3015) forming a metal contact layer (105) on the channel layer (104).

In step (3012), the nucleation layer (102) is formed on the substrate (101) with metal-organic chemical vapor deposition (MOCVD) or molecular beam epitoxy (MBE).

In step (3013), forming a buffer layer (103) on the nucleation layer (102) uses metal-organic chemical vapor deposition (MOCVD) or molecular beam epitoxy (MBE).

In step (3014), forming a channel layer (104) on the buffer layer (103) uses metal-organic chemical vapor deposition (MOCVD) or molecular beam epitoxy (MBE).

In step (3015), forming a metal contact layer (105) on the channel layer (104) uses metal-organic chemical vapor deposition (MOCVD) or molecular beam epitoxy (MBE).

In step (302), forming a drain (11) and a source (12) on the semiconductor substrate (10) may comprise steps of forming a first photoresistor layer on an operational area of the transistor (1) by a photoetching technique, defining the operational area by a dry etching technique and forming a second photoresistor layer on the drain (11) and the source (12) by a photoetching technique and may have a operation temperature and an annealing time.

The photoresistor layer is formed on the metal contact layer (105). The dry etching technique etches the substrate (101) by an inductively coupled plasma reactive ion etch technique. The operation temperature may be in a range of 200 degrees Celsius to 1000 degrees Celsius. The annealing time may be in a range of 3 seconds to 30 minutes.

In step (304) of forming the gate metal seed layer (13) on the semiconductor substrate (10) by a sensitization process and an activation process, the sensitization process may comprise steps of immersing the semiconductor substrate in a sensitization solution of acid stannous ions for one to thirty minutes and washing the semiconductor substrate (10) with deionized water.

The sensitization solution may comprise a sensitizer that is selected from a group consisting of stannous chloride (SnCl₂), titanium trichloride (TiCl₃) and stannous sulfate (SnSO₄).

The activation process may be executed after the sensitization process, may be executed many times with the sensitization process to reduce the size of gate unit particle (141) and may comprise steps of immersing the semiconductor substrate in an activation solution of acid palladium ions for one to thirty minutes and washing the semiconductor substrate (10) with deionized water.

The activation solution may comprise an activator that is selected from a group consisting of silver nitrate (AgNO₃), palladium chloride (PdCl₂) and auric chloride (AuCl₃).

In step (305) of forming a Gate Schottky contact (14) on the gate metal seed layer (13) by an electroless plating approach may have a deposit time and a deposit temperature. The deposit time may be in a range of 1 second to 5 hours. The deposit temperature may be in a range of 5 degrees Celsius to 150 degrees Celsius.

The electroless plating approach may comprise steps of immersing the semiconductor substrate (10) in an alkaline bath electroless plating to deposit the Gate Schottky contact (13) at room temperature and washing the semiconductor substrate with deionized water. The alkaline bath electroless plating may comprise a precursor, a pH buffer, a reducing agent, a complexing agent and a stabilizer and may have a pH value that is in a range of 6 to 13.

The precursor may be selected from a group consisting of palladium chloride (PdCl₂), silver nitrate (AgNO₃), nickel chloride (NiCl₂) and Chloroplatinic acid (H₂PtCl₆. 2H₂O). The pH buffer may be selected from a group consisting of boric acid (H₃BO₃), ammonium hydroxide (NH₄OH) and sodium hydroxide (NaOH). The reducing agent may be selected from a group consisting of hydrazine, hypophosphite, borohydride and formaldehyde. The complexing agent may be selected from a group consisting of ethylenediamine, tetramethylethylenediamine, ammonium chloride and ethylenediamin tetraacetic acid. The stabilizer may be selected from a group consisting of thiourea and thiodiglycolic acid.

Various changes can be made without departing from the broad spirit and scope of the invention.

What is claimed is:

1. A transistor device comprising
a semiconductor substrate;
a drain forming on the semiconductor substrate;
a source forming on the semiconductor substrate and not overlapping the drain;
a gate metal seed layer forming on the semiconductor substrate, not overlapping the drain and the source and comprising a gelatinous substance layer and multiple metal seed crystals; and
a gate Schottky contact forming on the gate metal seed layer.

2. The transistor device as claimed in claim 1, wherein the semiconductor substrate comprises
a substrate;
a nucleation layer forming on the substrate;
a buffer layer forming on the nucleation layer;
a channel layer forming on the buffer layer; and
a metal contact layer forming on the channel layer.

3. The transistor device as claimed in claim 1, wherein
the gelatinous substance layer has a thickness in a range of 5 angstroms (Å) to 20 angstroms (Å); and
the secondary metal seed crystals forming on the gelatinous substance layer and are selected from a group consisting of a palladium (Pd) seed crystals, a silver (Ag) seed crystals, and a gold (Au) seed crystals.

4. The transistor device as claimed in claim 1, wherein the transistor is applied to a hydrogen sensor.

5. The transistor device as claimed in claim 3, wherein the gate metal seed layer has a thickness in a range of 1 angstrom (Å) to 5000 angstrom (Å).

6. The transistor device as claimed in claim 5, wherein the gate Schottky contact consists of multiple gate unit particles selected from a group consisting of palladium (Pd), platinum (Pt), nickel (Ni), and palladium-silver (Pd—Ag).

7. The transistor device as claimed in claim 5, wherein the gate Schottky contact has a thickness in a range of 2 angstroms (Å) to 50,000 angstroms (Å).

8. A manufacture method comprising steps of
providing a semiconductor substrate;
forming a drain and a source on the semiconductor substrate;
forming a patterned photoresist layer with a photolithography to define a gate area on the semiconductor substrate;
forming a gate metal seed layer on the semiconductor substrate with a sensitization process and an activation process; and
forming a gate Schottky contact on the gate metal seed layer with an electroless plating approach.

9. The manufacture method as claimed in claim 8, wherein the providing a semiconductor substrate step comprises steps of
providing a substrate;
forming a nucleation layer on the substrate;
forming a buffer layer on the nucleation layer;
forming a channel layer on the buffer layer; and
forming a metal contact layer on the channel layer.

10. The manufacture method as claimed in claim 8, wherein the sensitization process of the forming the gate metal seed layer step comprises
immersing the semiconductor substrate in a sensitization solution of acid stannous ions for one to thirty minutes; and
washing the semiconductor substrate by deionized water.

11. The manufacture method as claimed in claim 8, wherein the activation process of the forming the gate Schottky contact is executed after the sensitization process and comprises
immersing the semiconductor substrate in an activation solution of acid palladium ions for one minute to thirty minutes; and
washing the semiconductor substrate by deionized water.

12. The manufacture method as claimed in claim 8, wherein the electroless plating approach of the forming a gate Schottky contact step comprising steps of
immersing the semiconductor substrate in an alkaline bath electroless plating to deposit the gate Schottky contact at room temperature; and
washing the semiconductor substrate by deionized water.

13. The manufacture method as claimed in claim 8, wherein the forming a drain and a source step has
a operation temperature in a range of 200 degrees Celsius to 1000 degrees Celsius; and
an annealing time in a range of 3 seconds to 30 minutes.

14. The manufacture method as claimed in claim 10, wherein the sensitization solution comprises a sensitizer selected from a group consisting of stannous chloride (SnCl₂), titanium trichloride (TiCl₃) and stannous sulfate (SnSO₄).

15. The manufacture method as claimed in claim 11, wherein the activation solution comprises an activator that is selected from a group consisting of silver nitrate (AgNO₃), palladium chloride (PdCl₂) and auric chloride (AuCl₃).

16. The manufacture method as claimed in claim 12, wherein the alkaline bath electroless plating comprises a precursor, a pH buffer, and a reducing agent.

17. The manufacture method as claimed in claim 12, wherein the forming a gate Schottky contact step has a deposit time that is with a reasonably range of 1 second to 5 hours.

18. The manufacture method as claimed in claim 13, wherein the forming a drain and a source step has
an operation temperature in a range of 200 degrees Celsius to 1000 degrees Celsius; and
an annealing time in a range of 3 seconds to 30 minutes.

19. The manufacture method as claimed in claim 16, wherein the alkaline bath electroless plating further comprises a complexing agent.

20. The manufacture method as claimed in claim 16, wherein the alkaline bath electroless plating further comprises a complexing agent and a stabilizer.

21. The manufacture method as claimed in claim 16, wherein the precursor is selected from the group consisting of palladium chloride (PdCl₂), silver nitrate (AgNO₃), nickel chloride (NiCl₂) and chloroplatinic acid (H₂PtCl₆.2H₂O).

22. The manufacture method as claimed in claim 16, wherein the pH buffer is selected from a group consisting of boric acid (H₃BO₃), ammonium hydroxide (NH₄OH) and sodium hydroxide (NaOH).

23. The manufacture method as claimed in claim 16, wherein the reducing agent is selected from a group consisting of hydrazine, hypophosphite, borohydride and formaldehyde.

24. The manufacture method as claimed in claim 16, wherein the alkaline bath electroless plating has a pH value in a range of 6 to 13.

25. The manufacture method as claimed in claim 19, wherein the complexing agent is selected from the group consisting of ethylenediamine, tetramethylethylenediamine, ammonium chloride and ethylenediamin tetraacetic acid.

26. The manufacture method as claimed in claim 20, wherein the stabilizer is selected from a group consisting of thiourea and thiodiglycolic acid.
